(19) United States
(12) Patent Application Publication
(10) Pub. No.: US 2025/0232974 A1
(43) Pub. Date: Jul. 17, 2025

(54) METHOD OF FILLING A GAP

(71) Applicant: ASM IP Holding B.V., Almere (NL)

(72) Inventors: Sungdae Woo, Hwaseong-si (KR); René Henricus Jozef Vervuurt, Leuven (BE)

(21) Appl. No.: 19/013,556

(22) Filed: Jan. 8, 2025

Related U.S. Application Data
(60) Provisional application No. 63/619,809, filed on Jan. 11, 2024.

(51) Int. Cl. H01L 21/02; C23C 16/04; C23C 16/40; C23C 16/455

(52) U.S. Cl. CPC H01L 21/0228; C23C 16/045; C23C 16/405; C23C 16/45536; C23C 16/45553; H01L 21/02186; H01L 21/02274

(57) ABSTRACT

A method of filling a gap provided to a substrate, comprises: providing the substrate in a reactor, and performing a flowable gap-fill cycle repeatedly, the flowable gap-fill cycle includes forming a first solid layer on the surface of the gap, turning the first solid layer into a flowable layer by supplying a fluorine flow amount of a fluorine source activated by a power, and converting the flowable layer into a second solid layer. The method of filling a gap comprises calculating a ratio of fluorine flow amount to thickness of the first solid layer and controlling the fluorine flow amount based on the calculated ratio.

### CROSS-REFERENCE TO RELATED APPLICATIONS

This application claims priority to U.S. Provisional Patent Application Ser. No. 63/619,809 filed Jan. 11, 2024 titled METHOD OF FILLING A GAP, the disclosure of which is hereby incorporated by reference in its entirety.

### FIELD OF INVENTION

One or more embodiments relate to a method of filling a gap, and more particularly, to a method of filling a gap to prevent a gap structure from being damaged in a flowable gap fill process and to fill the gap without a void or a seam.

### BACKGROUND OF THE DISCLOSURE

In manufacturing a semiconductor device, a gap fill process to fill the gap with an insulating layer (e.g., SiO₂, SiN, TiO₂ etc.) is performed in various unit processes (e.g., isolation process, patterning process and VNAND gate process etc.). When the gap is filled incompletely with the insulating layer, a void or a seam remains in the gap and a device performance becomes low accordingly due to an electrical short or a leak, for instance. Therefore, it is required for the gap to be filled with the insulating layer without a void or a seam.

In order to solve this problem, a flowable gap fill method was introduced. Filling the gap with a flowable insulating layer is an effective void-free or seamless gap fill method as the flowability of the layer enables to fill the gap more effectively from the bottom of the gap without a void or a seam.

In a gap fill process to fill the gap with TiO₂ layer, the solid TiO₂ layer formed on the surface of the gap may become flowable by exposing the solid TiO₂ layer to a fluorine source activated by a power (e.g., NF₃ plasma). However, the fluorine may damage a gap structure (e.g., SOH (spin-on-hardmask) layer). Therefore, a protective layer may be formed on the surface of the gap, followed by forming the TiO₂ layer thereon.

A protective layer, a HfO₂ layer, for instance, may be formed on the surface of the gap before forming the TiO₂ layer. However, a delamination may occur between TiO₂ layer and HfO₂ layer in the subsequent process such as annealing process due to different properties (e.g., different thermal expansion coefficients), resulting in incomplete filling of the gap (e.g., seam or void).

Therefore, it is required to introduce a method of filling a gap in which the gap structure may be protected from the fluorine.

### SUMMARY OF THE DISCLOSURE

The present disclosure discloses a method of forming a protective layer to prevent the gap structure from being damaged by a fluorine in a flowable TiO₂ gap fill process and to fill the gap without a void or a seam, and a method of preventing an delamination between the protective layer and the TiO₂ layer formed thereon to fill the gap.

In some embodiments, a method of filling a gap provided to a substrate may comprise: providing the substrate in a reactor, and performing a flowable gap-fill cycle repeatedly. The flowable gap-fill cycle may comprise forming a first solid layer on the surface of the gap, turning the first solid layer into a flowable layer by supplying a fluorine flow amount of a fluorine source activated by a power to the first solid layer, and converting the flowable layer into a second solid layer.

The method of filling a gap may further comprise calculating a ratio of the fluorine flow amount to a thickness of the first solid layer and controlling the fluorine flow amount based on the calculated ratio.

In some embodiments, the fluorine flow amount may be equal to a flow rate of the fluorine source multiplied by a fluorine source supply time, wherein controlling the fluorine flow amount comprises controlling at least one of the flow rate of the fluorine source and the fluorine source supply time.

In some embodiments, calculating the ratio of fluorine flow amount to the thickness of the first solid layer may comprise multiplying the flow rate (sccm) of the fluorine source by the fluorine supply time (second) divided by the thickness (nm) of the first solid layer.

In some embodiments, the ratio of fluorine flow amount to the thickness of the first solid layer may be 1,000:1 sccm-second/nm or below.

In some embodiments, the flowable gap-fill cycle may be repeated until the gap is filled with the second solid layer.

In some embodiments, the gap may comprise an upper surface, a lower surface, and a side surface connecting the upper surface and the lower surface, and the first solid layer may be formed on the upper surface, the lower surface, and the side surface.

In some embodiments, a portion of the first solid layer formed on the upper surface and the side surface may be fluorinated into the flowable layer. The flowable layer on the upper surface and the side surface may flow into the lower surface.

In some embodiments, the first solid layer may comprise the same material as the second solid layer.

In some embodiments, the first solid layer may comprise a titanium oxide.

In some embodiments, the first solid layer may be formed by repeating a cycle comprising: supplying a titanium source, followed by supplying an oxygen source, wherein the oxygen source may be activated by a power.

In some embodiments, the titanium source may comprise at least one of titanium tetrakis(isopropoxide) (Ti(O-iPr)₄), titanium halide, cyclopentadienyl titanium, titanium bis(isopropoxide)bis(2,2,6,6-tetramethyl-3,5-heptanedionate) (Ti(O-iPr)₂(thd)₂), tetrakisdimethylaminotitanium (Ti[N(CH₃)₂]₄, TDMAT), tetrakis(diethylamino)titanium ((Et₂N)₄Ti, TEMAT), or mixtures thereof.

In some embodiments, the oxygen source may comprise at least one of O₂, O₃, H₂O, H₂O₂, NO, N₂O, NO₂, CO, CO₂, or mixtures thereof.

In some embodiments, the flowable layer may comprise TiOₓF_{y}.

In some embodiments, the second solid layer may comprise a titanium oxide.

In some embodiments, the fluorine source may comprise at least one of F₂, SF₆, CF₄, C₂F₆, CHF₃, CH₂F₂, ClF₃, NF₃, C₃F₈, C₄F₈, HF, SiF₄, or mixtures thereof.

In some embodiments, converting the flowable layer may be performed by a plasma treatment.

In some embodiments, the plasma treatment may be performed by supplying an oxygen source comprising at least one of O₂, O₃, H₂O, H₂O₂, NO, N₂O, NO₂, CO, CO₂, or mixtures thereof, wherein the oxygen source may be activated by a power.

In some embodiments, a method of filling a gap may comprise: providing a substrate in a reactor, wherein the substrate comprises the gap, forming a first solid layer on the surface of the gap, turning the first solid layer into a first flowable layer by supplying a fluorine source activated by a power to a the first solid layer, converting the first flowable layer into a second solid layer, forming a third solid layer on the second solid layer, turning the third solid layer into a second flowable layer by supplying the fluorine source activated by the power to the third solid layer, and converting the second flowable layer into a fourth solid layer. The first solid layer may be thicker than the third solid layer.

In some embodiments, a thickness of the first solid layer may be about ₅ nm or more.

In some embodiments, a thickness of the third solid layer may be about ₃ nm or less.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a flowchart schematically illustrating a method of filling a gap according to an embodiment.

FIG. 2 is a detailed flowchart illustrating a method of performing a flowable gap-fill cycle repeatedly according to an embodiment.

FIG. 3 is a side cross-sectional view illustrating a method of performing a flowable gap-fill cycle in the first cycle.

FIG. 4 is a side cross-sectional view illustrating a method of performing a flowable gap-fill cycle in the second cycle subsequent to the first cycle.

FIG. 5A and FIG. 5B are side cross-sectional views illustrating a fluorination of the TIO₂ layer as the first solid layer depending on the thickness of the TiO₂ layer.

FIG. 6 is a graph for illustrating atomic percentages of a gap structure according to an embodiment.

FIGS. 7A and 7B are images illustrating a profile of TiO₂ layer filling a gap structure according to an embodiment.

FIG. 8 is a timing diagram illustrating a method of filling a gap according to an embodiment.

### DETAILED DESCRIPTION OF EXEMPLARY EMBODIMENTS

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Hereinafter, one or more embodiments will be described more fully with reference to the accompanying drawings.

In this regard, the present embodiments may have different forms and should not be construed as being limited to the descriptions set forth herein. Rather, these embodiments are provided so that the disclosure will be thorough and complete, and will fully convey the scope of the disclosure to one of ordinary skill in the art.

The terminology used herein is for describing particular embodiments and is not intended to limit the disclosure. As used herein, the singular forms “a”, “an”, and “the” are intended to include the plural forms as well, unless the context clearly indicates otherwise. It will be further understood that the terms “includes”, “comprises” and/or “including”, “comprising” used herein specify the presence of stated features, integers, steps, processes, members, components, and/or groups thereof, but do not preclude the presence or addition of one or more other features, integers, steps, processes, members, components, and/or groups thereof. As used herein, the term “and/or” includes any and all combinations of one or more of the associated listed items.

It will be understood that, although the terms first, second, etc. may be used herein to describe various members, components, regions, layers, and/or sections, these members, components, regions, layers, and/or sections should not be limited by these terms. These terms do not denote any order, quantity, or importance, but rather are only used to distinguish one component, region, layer, and/or section from another component, region, layer, and/or section. Thus, a first member, component, region, layer, or section discussed below could be termed a second member, component, region, layer, or section without departing from the teachings of embodiments.

In the specification, “gas” may include evaporated solids and/or liquids and may include a single gas or a mixture of gases. In the specification, a process gas introduced into a reaction chamber through a shower head may include a precursor gas and an additive gas.

The precursor gas and the additive gas may typically be introduced as a mixed gas or may be separately introduced into a reaction space. The precursor gas may be introduced together with a carrier gas such as an inert gas. The additive gas may include a dilution gas such as a reactive gas and an inert gas. The reactive gas and the dilution gas may be mixedly or separately introduced into the reaction space.

The precursor may include two or more precursors, and the reactive gas may include two or more reactive gases. The precursor may be a gas that is chemisorbed onto a substrate and typically contains metalloid or metal elements constituting a main structure of a matrix of a dielectric film, and the reactive gas for deposition may be a gas that is reactive with the precursor chemisorbed onto the substrate when excited to fix an atomic layer or a monolayer on the substrate. The term “chemisorption” may refer to chemical saturation adsorption.

A gas other than the process gas, that is, a gas introduced without passing through the shower head, may be used to seal the reaction space, and it may include a seal gas such as an inert gas.

In some embodiments, the term “film” may refer to a layer that extends continuously in a direction perpendicular to a thickness direction without substantially having pinholes to cover an entire target or a relevant surface or may refer to a layer that simply covers a target or a relevant surface. In some embodiments, the term “layer” may refer to a structure, or a synonym of a film, or a non-film structure having any thickness formed on a surface.

The film or layer may include a discrete single film or layer or multiple films or layers having some characteristics, and the boundary between adjacent films or layers may be clear or unclear and may be set based on physical, chemical, and/or some other characteristics, formation processes or sequences, and/or functions or purposes of the adjacent films or layers.

In the specification, the expression “containing an Si—N bond” may be referred to as characterized by an Si—N bond or Si—N bonds having a main skeleton substantially constituted by the Si—N bond or Si—N bonds and/or having a substituent substantially constituted by the Si—N bond or Si—N bonds. A silicon nitride layer may be a dielectric layer containing a Si—N bond, and may include a silicon nitride layer (SiN) and a silicon oxynitride layer (SiON).

In the specification, the expression “same material” should be interpreted as meaning that main components (constituents) are the same. For example, when a first layer and a second layer are both silicon nitride layers and are formed of the same material, the first layer may be selected from the group consisting of Si₂N, SiN, Si₃N₄, and Si₂N₃ and the second layer may also be selected from the above group, but a particular film quality thereof may be different from that of the first layer.

In addition, in the specification, according as an operable range may be determined based on a regular job, any two variables may constitute an operable range of the variable and any indicated range may include or exclude terminated sites. Additionally, the values of any indicated variables may refer to exact values or approximate values (regardless of whether they are indicated as “about”), may include equivalents, and may refer to an average value, a median value, a representative value, a majority value, or the like.

In the specification where conditions and/or structures are not specified, one of ordinary skill in the art may easily provide these conditions and/or structures as a matter of customary experiment in the light of the specification. In all described embodiments, any component used in an embodiment may be replaced with any equivalent component thereof, including those explicitly, necessarily, or essentially described herein, for intended purposes, and in addition, the disclosure may be similarly applied to devices and methods.

Hereinafter, embodiments of the disclosure will be described with reference to the accompanying drawings. In the drawings, variations from the illustrated shapes may be expected because of, for example, manufacturing techniques and/or tolerances. Thus, the embodiments of the disclosure should not be construed as being limited to the particular shapes of regions illustrated herein but may include deviations in shapes that result, for example, from manufacturing processes.

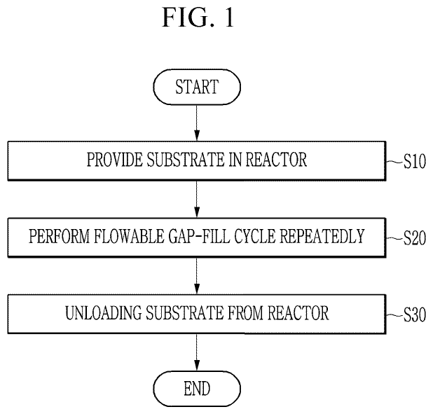

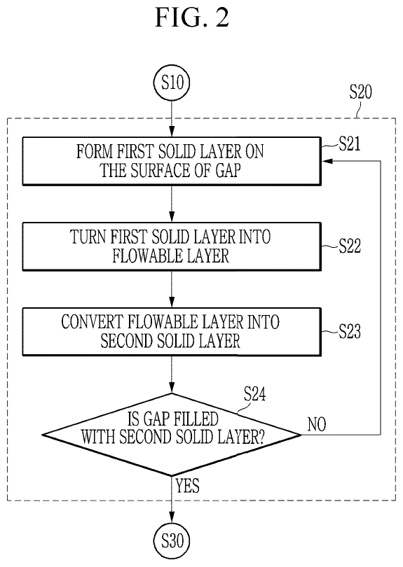

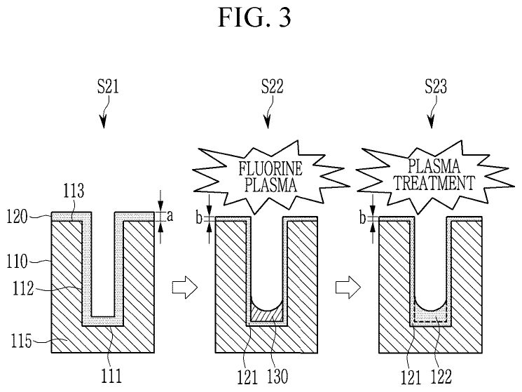

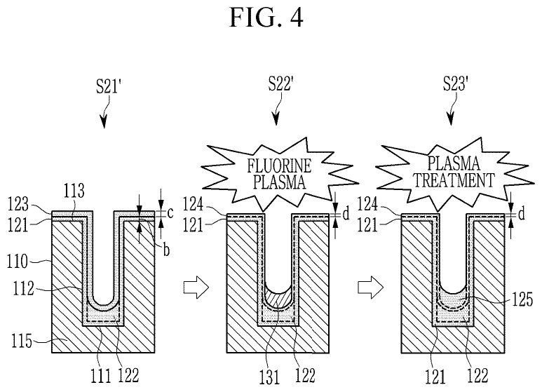

FIG. 1 is a flowchart schematically illustrating a method of filling a gap according to an embodiment. FIG. 2 is a detailed flowchart illustrating a method of performing a flowable gap-fill cycle repeatedly according to an embodiment. FIG. 3 is a side cross-sectional view illustrating a method of performing a flowable gap-fill cycle in the first cycle. FIG. 4 is a side cross-sectional view illustrating a method of performing a flowable gap-fill cycle in the second cycle subsequent to the first cycle.

Referring to FIGS. 1 and 2, a method of filling a gap according to an embodiment may comprise providing a substrate in a reactor in step S10, performing a flowable gap-fill cycle repeatedly in step S20, and unloading the substrate from the reactor in step S30.

In detail, the step S20 may comprise forming a first solid layer on the surface of the gap in step S21, turning the first solid layer into a flowable layer in step S22, converting the flowable layer into a second solid layer in step S23.

After converting into the second solid layer, it is determined whether the gap is filled with the second solid layer or not in step S24. When the gap is filled with the second solid layer, performing a flowable gap-fill cycle may end, and then the substrate may be unloaded from the reactor in step S30.

However, when the gap is not filled with the second solid layer, the step S21 to the step S23 may be repeated a plurality of times. Accordingly, the flowable gap-fill cycle may be repeated a plurality of times until the gap is filled with the second solid layer. The second solid layer herein may be referred to as all solid layers formed in the subsequent cycles after forming the first solid layer in the first cycle.

The method of filling a gap according to an embodiment may comprise calculating a ratio of a fluorine flow amount to a thickness of the first solid layer and controlling an amount of the fluorine flow amount based on the calculated ratio. Accordingly, the first solid layer formed on the gap may be thick enough to protect the gap structure from a fluorine. The gap structure may comprise hereinafter not only the surface of the gap but also the layer under the surface of the gap.

In some embodiments of the present disclosure, the first solid layer may be formed as the same material as the second solid layer. Therefore, a delamination due to different material properties (e.g., a thermal expansion coefficient) may be prevented between the first solid layer and the second solid layer in the subsequent processes (e.g., an annealing process).

Since the first solid layer and the second solid layer may be the same material, a protective layer process and a gap fill process may be performed in the same reactor in-situ. Therefore, the gap fill process may be simplified and the substrate processing time may be shorter, resulting in high throughput per unit time.

The fluorine flow amount may be equal to a flow rate (sccm) of the fluorine source multiplied by a fluorine source supply time (second). Accordingly, calculating the ratio of fluorine flow amount to the thickness of the first solid layer may comprise multiplying the flow rate of the fluorine source (sccm) by the fluorine source supply time (second) divided by the thickness (nm) of the first solid layer.

In some embodiments, the ratio of the fluorine flow amount to the thickness of the first solid layer may be 1,000:1 sccm·second/nm or below, such that the gap structure may not be damaged due to the sufficient thickness of the first solid layer.

On the contrary, when the ratio of the fluorine flow amount to the thickness of the first solid layer is greater than 1,000:1 sccm·second/nm, a fluorine flow amount may be excessive such that the first solid layer may not be thick enough to protect the gap structure from the fluorine, resulting in a damage to the gap structure.

Referring to FIGS. 1 and 3, in step S10, a substrate comprising a gap structure 110 may be provided to a reactor. The gap structure 110 of the substrate may comprise an upper surface 113, a lower surface 111, and a side surface 112 connecting the upper surface 113 and the lower surface 111.

The topography forming the upper surface 113 and the side surface 112 of the gap structure 110 may be a separate structure formed on a base substrate 115 having the lower surface 111 or may be integrated with the base substrate 115. The side surface 112 may extend generally perpendicular or at an angle with respect to the lower surface 111.

Referring to FIGS. 2 and 3, in step S20, a solid layer may be formed repeatedly on the substrate through the step S21 to the step S24.

In step S21, a first solid layer 120 may be formed on the upper surface 113, the lower surface 111 and the side surface 112 of the gap structure 110. In some embodiments, the first solid layer 120 may be formed to have a substantially uniform thickness along the surface of the gap. The first solid layer 120 may be formed by a Plasma Enhanced ALD (PEALD) method.

In some embodiments, the first solid layer 120 may comprise a titanium oxide. For example, the titanium oxide layer may be formed on the surface of the gap structure 110 by repeating a cycle comprising: supplying a titanium source, followed by supplying an oxygen source activated by a power.

In some embodiments, the titanium source may comprise at least one of titanium tetrakis(isopropoxide) (Ti(O-iPr)₄), titanium halide (TiCl₄), cyclopentadienyl titanium, titanium bis(isopropoxide)bis(2,2,6,6-tetramethyl-3,5-heptanedionate) (Ti(O-iPr)₂(thd)₂), tetrakisdimethylaminotitanium (Ti[N(CH₃)₂]₄, TDMAT), tetrakis(diethylamino)titanium ((Et₂N)₄Ti, TEMAT), or mixtures thereof.

In some embodiments, the oxygen source may comprise at least one of O₂, O₃, H₂O, H₂O₂, NO, N₂O, NO₂, CO, CO₂, or mixtures thereof.

In step S22, a portion of the first solid layer 120 may turn into a first flowable layer 130 by supplying a fluorine flow amount of a fluorine source activated by a power (i.e., fluorine plasma) to the first solid layer 120. In more detail, a portion of the first solid layer 120 formed on the upper surface 113 and the side surface 112 may be fluorinated by the fluorine source activated by a power and may flow into the lower surface 111, resulting in filling the gap with a flowable layer 130.

A portion of the first solid layer 120 may react with a fluorine and become flowable. The flowable layer may flow into the lower surface 111 along the side surface 112, resulting in filling the gap with the first flowable layer 130. A remaining portion 121 of the first solid layer 120 in step S22 may have the thickness b thinner than the thickness a of the first solid layer 120 in step S21. The first solid layer 120 may comprise a titanium oxide and the first flowable layer 130 may comprise TiOₓF_{y}.

In some embodiments, the fluorine source may comprise at least one of F₂, SF₆, CF₄, C₂F₆, CHF₃, CH₂F₂, ClF₃, NF₃, C₃F₈, C₄F₈, HF, SiF₄, or mixtures thereof.

In step S23, the first flowable layer 130 may be converted into a second solid layer 122 by plasma treatment. In this case, the second solid layer 122 may comprise the same material as the first solid layer 120. For instance, the first solid layer 121 may comprise a titanium oxide, and the second solid layer 122 may also comprise a titanium oxide. The remaining portion 121 of the first solid layer 120 in step S22 may maintain the thickness b in step S23.

In some embodiments, the plasma treatment may be performed by supplying an oxygen source comprising at least one of O₂, O₃, H₂O, H₂O₂, NO, N₂O, NO₂, CO, CO₂, or mixtures thereof, wherein the oxygen source may be activated by a power.

Referring to FIG. 4, a solid layer may be further formed repeatedly on the substrate through the step S21′ to the step S23′ of the second cycle subsequent to S21 to S23 of the first cycle. The step S21′ to the step S23′ of the second cycle may be substantially the same as the step S21 to the step S23 of the first cycle as shown in FIG. 3. Accordingly, the following description will focus on these differences.

In step S21′, a third solid layer 123 may be formed on the remaining portion 121 of the first solid layer 120 and the second solid layer 122. The third solid layer 123 may be formed to have a substantially uniform thickness c along the surface of the remaining portion 121 of the first layer 120 and the second solid layer 122. The third solid layer 123 may be formed by Plasma Enhanced ALD (PEALD) method.

In some embodiments, the thickness a of the first solid layer 120 in FIG. 3 may be thicker than the thickness c of the third solid layer 123 in FIG. 4, such that the remaining portion 121 of the first solid layer 120 may be thick enough to protect the gap structure 110 from the fluorine during a fluorination to the third layer 123 in step S22′ of the second cycle. For instance, when the thickness c of the third solid layer 123 is equal to or less than 3 nm, the thickness a of the first solid layer 120 may be equal to or more than 5 nm.

In other words, the first solid layer 120 may be formed thick enough to protect the gap structure from a fluorine in step S22′ of the second cycle even after the thickness a of the first layer 120 is reduced to the thickness b of the remaining portion 121 in steps S22.

In some embodiments, the third solid layer 123 may comprise a titanium oxide by performing a cycle comprising: supplying a titanium source, followed by supplying an oxygen source activated by a power.

In operation S22′, the third solid layer 123 may turn into a second flowable layer 131 by supplying a fluorine flow amount of a fluorine source activated by a power (i.e., fluorine plasma) to the third solid layer 123, and may flow into the lower surface 111 of the gap structure 110 (i.e., an upper surface of the second solid layer 122), resulting in filling the remaining space of the gap with the second flowable layer 131.

In more detail, a portion of the third solid layer 123 formed on the remaining portion 121 of the first solid layer 120 may be fluorinated by reacting with a fluorine source activated by a power and become the flowable layer 131, resulting in flowing into the upper surface of the second solid layer 122 to fill the gap.

A remaining portion 124 of the third solid layer 123 may have the thickness d thinner than the thickness c of the third solid layer 123 formed in step S21′. The third solid layer 123 may comprise a titanium oxide, and the flowable layer 131 may comprise TiOₓF_{y}.

In step S23′, the flowable layer 131 may be converted into a fourth solid layer 125 by plasma treatment. In this case, the fourth solid layer 125 may comprise the same material as the third solid layer 123. For example, the third solid layer 123 may comprise a titanium oxide, and the fourth solid layer 125 may also comprise a titanium oxide. The remaining portion 124 of the third solid layer 123 in step S22′ may maintain the thickness d in step S23′.

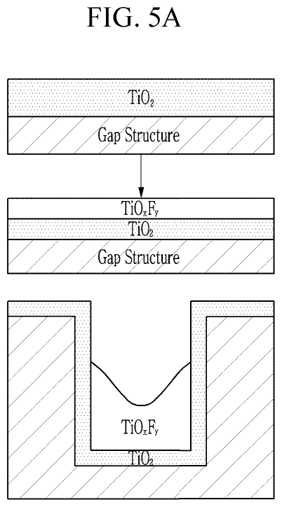

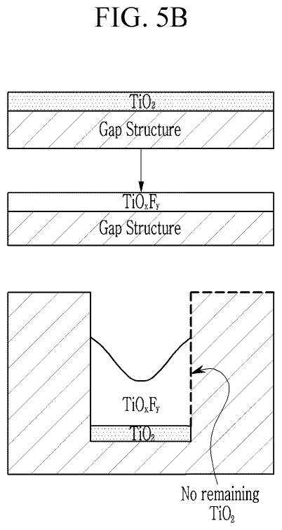

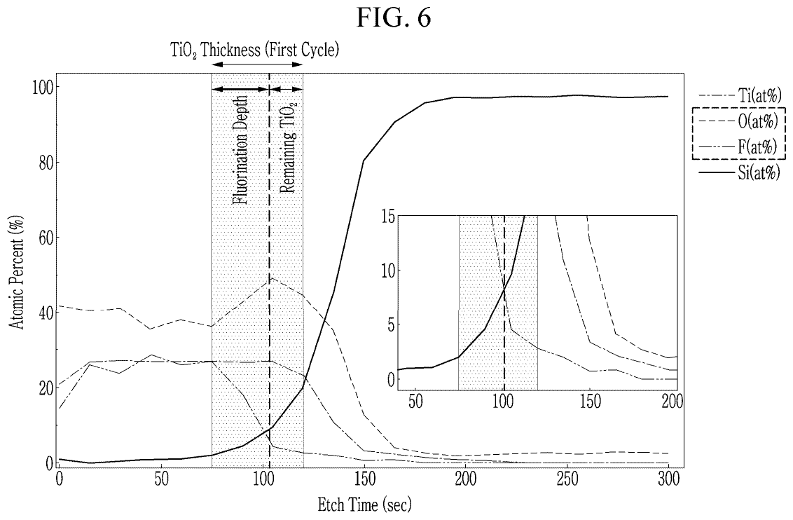

FIG. 5A and FIG. 5B are side cross-sectional views illustrating a fluorination of the TiO₂ layer as the first solid layer depending on the thickness of the TiO₂ layer. FIG. 6 is a graph for illustrating atomic percentages of a gap structure according to an embodiment.

Referring to FIG. 5A, a TiO₂ layer may be formed as a protection layer (i.e., a first solid layer 120 as shown in the step S21 of FIG. 3) before supplying a fluorine source.

In the method of filling a gap in FIG. 5A, the TiO₂ layer may be formed relatively thick in the first cycle on the gap structure (e.g., SOH layer), followed by fluorinating the TiO₂ layer by supplying a fluorine source activated by a power (i.e., NF₃ plasma) and reacting with the TiO₂ layer. In some embodiments, the thickness of the TiO₂ layer formed in the first cycle may be about 5 nm or more. The fluorinated TiO₂ layer may comprise TiOₓF_{y}.

Since the TiO₂ layer may be relatively thick, a portion of the TiO₂ layer may still remain during the fluorination and, therefore, prevent the gap structure from being damaged by the fluorine during the fluorination.

In FIG. 5B, on the contrary, a TiO₂ layer may be formed thin in the first cycle on the gap structure, compared to the thickness of the TiO₂ layer in FIG. 5A, followed by fluorinating the TiO₂ layer by supplying the fluorine flow amount of the fluorine source activated by a power (i.e., fluorine plasma) and reacting with the TiO₂ layer. In some embodiments, the thickness of the TiO₂ layer formed in the first cycle may be about 3 nm or less.

Since the TiO₂ layer may be relatively thin in FIG. 5B, the whole TiO₂ layer may be fluorinated into TiOₓF_{y} during the fluorination and the gap structure may be damaged by the fluorine. Therefore, forming a thick TiO₂ layer in the first cycle may be required to prevent the gap structure from being damaged by the fluorine source as shown in FIG. 5A.

After the first cycle, the subsequent cyclic process may be processed in which a TiO₂ layer with relatively thin thickness may be formed, followed by fluorinating the TiO₂ layer may be repeated a plurality of times.

The flow rate (sccm) of the fluorine source and the fluorine source supply time (second) to protect the gap structure from the fluorine may be determined by the ratio of the fluorine flow amount (sccm·second) to the thickness (nm) of the TiO₂ layer (i.e., a first solid layer) formed on the gap structure in the first cycle. The fluorine flow amount may be calculated by multiplying the flow rate (sccm) of the fluorine source by the fluorine source supply time (second).

In some embodiments, the ratio of the fluorine flow amount (sccm·second) to the thickness (nm) of the TiO₂ layer formed in the first cycle (i.e., a first solid layer) may be about 1,000:1 sccm·second/nm or below to protect the gap structure from the fluorine. Therefore, the flow rate of the fluorine source and the supply time of the fluorine source may be determined based on the thickness of the TiO₂ layer to be formed in the first cycle.

In another embodiments, the thickness of the TiO₂ layer to be formed in the first cycle may be determined based on the flow rate of the fluorine source and the supply time of the fluorine source.

For instance, when the thickness of the TiO₂ layer formed in the first cycle is 5 nm, the fluorine flow amount may be 5,000 sccm.second or below to meet the ratio 1,000:1 sccm·second/nm or below. In other words, the flow rate of the fluorine source and the supply time of the fluorine source may be determined within the range of the calculated fluorine flow amount. For instance, when the thickness of the TiO₂ layer is 5 nm, 200 sccm of NF₃ may be supplied for 25 seconds or below to protect the gap structure.

Referring to FIG. 6, the fluorinated layer may constitute a titanium, an oxygen and a fluorine (e.g., TiOₓF_{y}). The thickness of the TiO₂ layer and the fluorine flow amount may be controlled to remain the TiO₂ layer on the gap structure during the fluorination of the TiO₂ layer. The TiO₂ layer may remain due to a fluorination depth limitation.

For instance, the fluorination depth (e.g., a thickness of TiOₓF_{y} layer) may be less than 2 nm or 3 nm. Accordingly, forming about 5 nm or more thickness of TiO₂ layer on the gap structure may be preferable as a protective layer, such that the thickness of the remaining TiO₂ layer may be 3 nm or 2 nm after the fluorination.

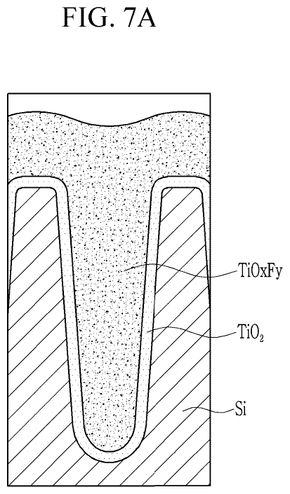

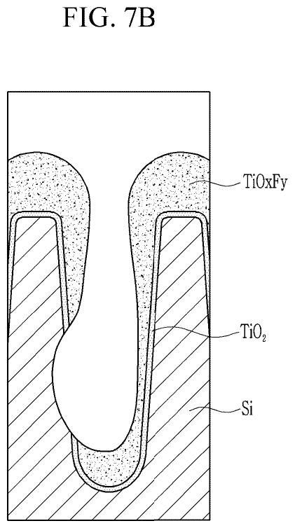

FIGS. 7A and 7B are images illustrating a profile of TiO₂ layer filling a gap structure according to an embodiment.

Referring to FIG. 7A, the gap structure is not damaged by the fluorine and protected by the remaining TiO₂ layer during the fluorination of the TiO₂ layer by NF₃ plasma. For instance, in the first cycle, a first TiO₂ layer with 7 nm thickness (i.e., a first solid layer) may be formed, followed by supplying 100 sccm of NF₃ for 45 seconds. That is, the ratio of the fluorine flow amount (100 sccm·45 seconds) to the thickness (7 nm) of the first TiO₂ layer formed in the first cycle is 643:1 sccm·second/nm (i.e., below 1,000:1 sccm·second/nm).

After forming the first TiO₂ layer (i.e., a first solid layer), followed by fluorinating the first TiO₂ layer into a first flowable layer (e.g., TiOₓF_{y} layer) to fill the gap, an oxygen source may be supplied to convert the first flowable layer into a second TiO₂ layer (i.e., a second solid layer).

In the subsequent cycles (e.g., a second cycle or more), a third TiO₂ layer with 2 nm thickness (i.e., a third solid layer) may be formed, followed by fluorinating the third TiO₂ layer into a second flowable layer (e.g., TiOₓF_{y} layer) by supplying 100 sccm of NF₃ for 45 seconds to fill the gap.

After that, an oxygen source may be supplied to convert the second flowable layer into a fourth TiO₂ layer (i.e., a fourth solid layer). Even though the ratio of the fluorine flow amount (100 sccm·45 seconds) to the thickness (2 nm) of the third TiO₂ layer formed in the subsequent cycles is 2,250:1 sccm·second/nm, greater than 1,000:1 sccm·second/nm, the gap structure may not be damaged since the first TiO₂ layer may be formed thick enough to protect the gap structure in the first cycle.

Referring to FIG. 7B, the gap structure may be damaged by the fluorine during the fluorination by NF₃ plasma due to the thin first TiO₂ layer. For instance, a TiO₂ layer with 3 nm thickness (i.e., a first solid layer) may be formed in the first cycle, followed by fluorinating the TiO₂ layer into the flowable layer (e.g., TiOₓF_{y} layer) by supplying 100 sccm of NF₃ for 45 seconds. The ratio of the fluorine flow amount (100 sccm·45 seconds) to the thickness (3 nm) of the first TiO₂ layer is 1,500:1 sccm·second/nm, greater than 1,000:1 sccm·second/nm. Thus, the gap structure may be damaged from the fluorine.

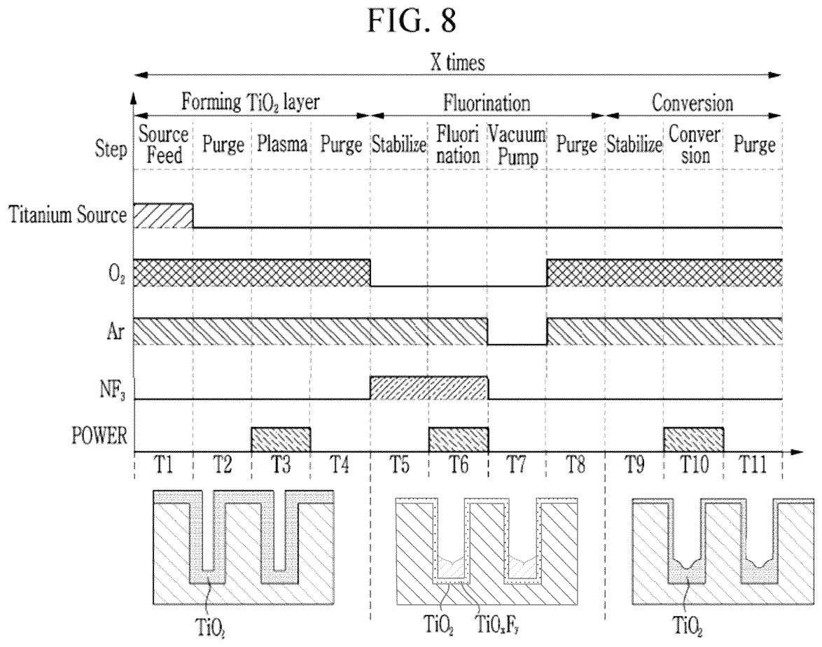

FIG. 8 is a timing diagram illustrating a method of filling a gap according to an embodiment.

Referring to FIG. 8, a titanium source may be supplied at T1 and an oxygen source (e.g., O₂) may be supplied continuously throughout T1 to T4. Then, the oxygen source may be activated at T3 by applying a power to a reactor to form a TiO₂ layer on the substrate mounted on the reactor. A purge steps may be provided at T2 after supplying the titanium source and before applying the power, and at T4 after turning off the power.

After forming the TiO₂ layer, a fluorination may be performed from T5 to T8 by supplying NF₃ activated by the power at T6, such that a flowable TiOₓF_{y} layer may be formed on the TiO₂ layer. The NF₃ and Ar may be supplied at T5 to stabilize the gas flow in the reactor, followed by being activated by the power at T6 to fluorinate the TiO₂ layer. After the power is turned off, the reactor may be purged without supplying a gas at T7 (i.e., a vacuum purge step by a vacuum pump only), followed by a purge step at T8 by supplying Ar and oxygen source.

Next to the fluorination, a conversion may be performed from T9 to T11 by supplying the oxygen source. The oxygen source may be activated at T10 by the power. In the conversion step, the flowable TiOₓF_{y} layer may be converted into the TiO₂ layer.

The above gap filling process may be repeated a plurality of times (X times) until the gap is filled with the TiO₂ layer.

Table 1 shows test conditions to perform the method of filling a gap according to an embodiment.

TABLE 1
Test conditions for filling a gap according to an embodiment.

| | | Step | | |
|---|---|---|---|---|
| Process parameters | | Forming TiO₂ layer | Fluorination | Conversion |
| Process time | Source feeding | 0.2 to 1.0 | — | — |
| per step | | (preferably 0.5 to | | |
| (second) | | 0.8) | | |
| | Source purge | 0.5 to 1.5 | 10 to 30 | 10 to 30 |
| | | (preferably 0.8 to | (preferably 15 to | (preferably 15 to |
| | | 1.2) | 25) | 25) |
| | RF- On | 0.2 to 1.0 | 10 to 40 | 20 to 40 |
| | (Activation of | (preferably 0.4 to | (preferably 20 to | (preferably 25 to |
| | reactant) | 0.8) | 40) | 35) |
| | Reactant purge | 0.1 to 0.5 | 20 to 50 | 10 to 20 |
| | | (preferably 0.2 to | (preferably 25 to | (preferably 12 to |
| | | 0.4) | 45) | 18) |
| Pressure (Pa) | | 200 to 300 | 600 to 1200 | 200 to 800 |
| | | (preferably 220 to | (preferably 800 to | (preferably 400 to |
| | | 280) | 1000) | 600) |
| Plasma | RF Power (W) | 100 to 300 | Remote plasma | 50 to 250 |
| condition | | (preferably 150 to | | (preferably 100 to |
| | | 250) | | 200 |
| | RF Frequency | 10 to 30 | | 10 to 30 |
| | (MHz) | | | |
| Gas flow rate | Source carrier | 1,000 to 3,000 | — | 1,000 to 3,000 |
| (sccm) | Ar | (preferably 1,500 to | | (preferably 1,500 to |
| | | 2,500) | | 2,500) |
| | Purge Ar | 2,000 to 5,000 | 100 to 300 | 100 to 300 |
| | | (preferably 3,000 to | (preferably 150 to | (preferably 150 to |
| | | 4,000) | 250) | 250) |
| | Oxygen source | 100 to 300 | — | 500 to 1,500 |
| | (reactant, O₂) | (preferably 150 to | | (preferably 800 to |
| | | 250) | | 1,200) |
| | Fluorine source | — | 50 to 150 | — |
| | (NF₃) | | (preferably 80 to | |
| | | | 120) | |

| | |
|---|---|
| Process temperature (° C.) | Room temperature to 100 |
| Source | Titanium-containing source |

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A method of filling a gap provided to a substrate, comprising:
providing the substrate in a reactor, and
performing a flowable gap-fill cycle repeatedly,
the flowable gap-fill cycle comprising:
forming a first solid layer on the surface of the gap;
turning the first solid layer into a flowable layer by supplying a fluorine flow amount of a fluorine source activated by a power to the first solid layer; and
converting the flowable layer into a second solid layer;
wherein the method comprises calculating a ratio of the fluorine flow amount to a thickness of the first solid layer and controlling the fluorine flow amount based on the calculated ratio.

2. The method of claim 1, wherein the fluorine flow amount is equal to a flow rate of the fluorine source multiplied by a fluorine source supply time,
wherein controlling the fluorine flow amount comprises controlling at least one of the flow rate of the fluorine source and the fluorine source supply time.

3. The method of claim 2, wherein calculating the ratio of the fluorine flow amount to the thickness of the first solid layer comprises multiplying the flow rate (sccm) of the fluorine source by the fluorine source supply time (second) divided by the thickness (nm) of the first solid layer.

4. The method of claim 3, wherein the ratio of the fluorine flow amount to the thickness of the first solid layer is 1,000:1 sccm·second/nm or below.

5. The method of claim 1, wherein the flowable gap-fill cycle is repeated a plurality of times until the gap is filled with the second solid layer.

6. The method of claim 1, wherein the gap comprises an upper surface, a lower surface, and a side surface connecting the upper surface and the lower surface, and the first solid layer is formed on the upper surface, the lower surface, and the side surface.

7. The method of claim 6, wherein a portion of the first solid layer formed on the upper surface and the side surface is fluorinated into the flowable layer and flows into the lower surface.

8. The method of claim 7, wherein the first solid layer comprises the same material as the second solid layer.

9. The method of claim 1, wherein the first solid layer comprises a titanium oxide.

10. The method of claim 9, wherein the first solid layer is formed by repeating a cycle comprising:
supplying a titanium source; and
supplying an oxygen source, wherein the oxygen source is activated by a power.

11. The method of claim 10, wherein the titanium source comprises at least one of titanium tetrakis(isopropoxide) (Ti(O-iPr)₄), titanium halide (TiCl₄), cyclopentadienyl titanium, titanium bis(isopropoxide)bis(2,2,6,6-tetramethyl-3,5-heptanedionate) (Ti(O-iPr)₂(thd)₂), tetrakisdimethylaminotitanium (Ti[N(CH₃)₂]₄, TDMAT), tetrakis(diethylamino)titanium ((Et₂N)₄Ti, TEMAT), or mixtures thereof.

12. The method of claim 10, wherein the oxygen source comprises at least one of O₂, O₃, H₂O, H₂O₂, NO, N₂O, NO₂, CO, CO₂, or mixtures thereof.

13. The method of claim 9, wherein the flowable layer comprises TiOₓF_{y}.

14. The method of claim 9, wherein the second solid layer comprises a titanium oxide.

15. The method of claim 1, wherein the fluorine source is at least one of F₂, SF₆, CF₄, C₂F₆, CHF₃, CH₂F₂, ClF₃, NF₃, C₃F₈, C₄F₈, HF, SiF₄, or mixtures thereof.

16. The method of claim 1, wherein converting the flowable layer is performed by a plasma treatment.

17. The method of claim 16, wherein the plasma treatment is performed by supplying an oxygen source comprising at least one of O₂, O₃, H₂O, H₂O₂, NO, N₂O, NO₂, CO, CO₂, or mixtures thereof, wherein the oxygen source is activated by a power.

18. A method of filling a gap, comprising:
providing a substrate in a reactor, wherein the substrate comprises the gap;
forming a first solid layer on the surface of the gap;
turning the first solid layer into a first flowable layer by supplying a fluorine source activated by a power to the first solid layer;
converting the first flowable layer into a second solid layer;
forming a third solid layer on the second solid layer;
turning the third solid layer into a second flowable layer by supplying the fluorine source activated by the power to the third solid layer; and
converting the second flowable layer into a fourth solid layer,
wherein the first solid layer is thicker than the third solid layer.

19. The method of claim 18, wherein a thickness of the first solid layer is about 5 nm or more.

20. The method of claim 19, wherein a thickness of the third solid layer is about 3 nm or less.
